(19) United States
(12) Patent Application Publication
(10) Pub. No.: US 2016/0093508 A1
(43) Pub. Date: Mar. 31, 2016

(54) METHOD OF MANUFACTURING SEMICONDUCTOR DEVICE, SUBSTRATE PROCESSING APPARATUS, AND NON-TRANSITORY COMPUTER-READABLE RECORDING MEDIUM

(71) Applicant: HITACHI KOKUSAI ELECTRIC INC., Tokyo (JP)

(72) Inventor: Arito OGAWA, Toyama-shi (JP)

(73) Assignee: HITACHI KOKUSAI ELECTRIC INC., Tokyo (JP)

(21) Appl. No.: 14/858,219

(22) Filed: Sep. 18, 2015

(30) Foreign Application Priority Data
Sep. 30, 2014 (JP) 2014-200885

(51) Int. Cl. H01L 21/322; C23C 16/455; C23C 16/52

(52) U.S. Cl. CPC H01L 21/3221; C23C 16/52; C23C 16/455

(57) ABSTRACT

The present invention provides a technology that includes: forming an intermediate film on a substrate having an insulating film formed thereon; and forming a metal film on the intermediate film. The intermediate film is more susceptible to oxidation than the metal film and has a smaller thickness than the metal film.

### BACKGROUND OF THE INVENTION

1. Field of the Invention

The present invention relates to a method of manufacturing a semiconductor device, a substrate processing apparatus, and a non-transitory computer-readable recording medium. More specifically, the present invention relates to a method of manufacturing a semiconductor device which has a process of forming metal and other films for use in, for example, gate electrodes of metal-oxide-semiconductor field effect transistors (MOSFETs), capacitor electrodes of dynamic random access memories (DRAMs), and wires of large scale integrations (LSIs), and a substrate processing apparatus and a non-transitory computer-readable recording medium for use in this process.

2. Description of the Related Art

With increasing integration scales and performances of MOSFETs, the thickness of the gate insulating films has been decreased, or the equivalent oxide thickness (EOT) scaling has been performed. In many cases, the gate electrodes of MOSFETs and the capacitor electrodes of DRAMs are formed of metallic nitride films that have good resistance to oxidation. In addition, a material for the electrode can be a parameter of a MOSFET, because the work function of the electrode determines the threshold voltage required to be controlled for the operation.

Some contemporary MOSFETs feature a stack structure including a metal film as an electrode and a high-k gate insulating film (refer to JP 2012-231123 A).

### SUMMARY OF THE INVENTION

Films with a high work function, including a tungsten nitride film, a cobalt film, and a nickel film, are typically resistant to oxidation. Therefore, oxygen contained in the gate insulating film or external oxygen having entered into the gate insulating film through the metal film may oxidize the silicon substrate, leading to increasing the EOT.

An object of the present invention is to provide a technology to increase a work function while reducing a factor of fluctuation of an EOT.

One aspect of the present invention provides a technology including: forming an intermediate film on a substrate having an insulating film formed thereon; and forming a metal film on the intermediate film. The intermediate film is more susceptible to oxidation than the metal film and has a smaller thickness than the metal film.

According to one aspect of the present invention, there is provided a technology to increase a work function while reducing a factor of fluctuation of an EOT.

### BRIEF DESCRIPTION OF THE DRAWINGS

FIG. 1 is a flowchart for explaining a method of manufacturing a gate electrode in one embodiment of the present invention;

FIG. 2 illustrates a schematic, vertical cross section of a MOSFET, for explaining the gate electrode in one embodiment of the present invention;

FIG. 3 is a graph showing C-V characteristics when a gate electrode is formed of a TiN film and when a gate electrode is formed of a WN film;

FIG. 4 is an EOT-HfO₂ physical film thickness plot when a gate electrode is formed of a TiN film and when a gate electrode is formed of a WN film;

FIG. 5A is a graph illustrating the oxidation of a gate electrode when the gate electrode is formed of a TiN film;

FIG. 5B is a graph illustrating the oxidation of a substrate when a gate electrode is formed of a WN film;

FIG. 6 is a schematic exemplary cluster apparatus used suitably when a MOSFET in a preferred embodiment of the present invention is manufactured;

FIG. 7 is another schematic exemplary cluster apparatus used suitably when a MOSFET in a preferred embodiment of the present invention is manufactured;

FIG. 8 is a block diagram of the controller in a cluster apparatus of FIG. 6 or 7;

FIG. 9A is a schematic cross section of a capacitor section in which top and bottom capacitor electrodes are made of WN films, a capacitor insulating film is an HfO₂ film, and intermediate films between the top capacitor electrode and the capacitor insulating film and between the bottom capacitor electrode and the capacitor insulating film are TiN films;

FIG. 9B is a schematic cross section of a capacitor section in which top and bottom capacitor electrodes are made of WN films, a capacitor insulating film is an HfO₂ film, and an intermediate film between the bottom capacitor electrode and the capacitor insulating film is a TiN film;

FIG. 9C is a schematic cross section for explaining a capacitor section in which top and bottom capacitor electrodes are made of WN films, a capacitor insulating film is an HfO₂ film, and an intermediate film between the top capacitor electrode and the capacitor insulating film is a TiN film;

FIG. 10 is a schematic cross section for explaining a MOSFET in which an intermediate film is a TiN film, a part of which has been left unoxidized; and

FIG. 11 is a schematic cross section for explaining a MOSFET in which an intermediate film is a TiN film, an entire of which has been oxidized.

### DETAILED DESCRIPTION OF THE PREFERRED EMBODIMENTS

Preferred embodiments of the present invention will be described below with reference to the accompanying drawings.

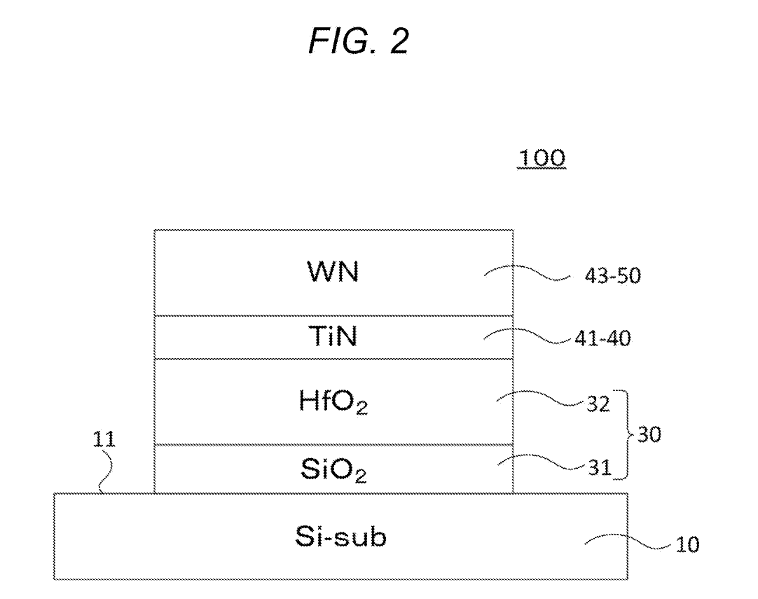

As illustrated in FIG. 2, a MOSFET 100, which is a semiconductor device in a preferred embodiment of the present invention, includes a silicon substrate (silicon wafer) 10 as a substrate (semiconductor substrate). Formed on a principal surface 11 of the silicon substrate 10 is a gate insulating film 30 as an insulating film. Formed on the gate insulating film 30 is an intermediate film 40. Formed on the intermediate film 40 is a metal film 50 as a gate electrode.

The gate insulating film 30 includes a SiO₂ film 31 and an HfO₂ film 32; the SiO₂ film 31 is formed on the principal surface 11 of the silicon substrate (Si substrate) 10, and the HfO₂ film 32 is formed on the SiO₂ film 31 as a high dielectric constant (high-k) insulating film. The HfO₂ film 32 as a high dielectric constant insulating film helps the decrease in a gate leak current.

A material for the intermediate film 40 is more susceptible to oxidation than the metal film 50 forming the gate electrode and has a lower work function than that for the metal film 50. In addition, the intermediate film 40 has a smaller thickness than the metal film 50. In this embodiment, a TiN film 41, which is a metal-containing film, is formed as the intermediate film 40.

The material for the metal film 50 is more resistant to oxidation than the intermediate film 40 and has a higher work function than that for the intermediate film 40. In addition, the metal film 50 has a larger thickness than the intermediate film 40. In this embodiment, a WN film 43 is formed as the metal film 50.

As described above, structures of the MOSFET 100 in this embodiment include: the HfO₂ film 32, which is a high dielectric constant insulating film forming the gate insulating film 30; the WN film 43, which forms the gate electrode as the metal film 50; and the TiN film 41 between the HfO₂ film 32 and the WN film 43, which forms the intermediate film 40 as a metal film.

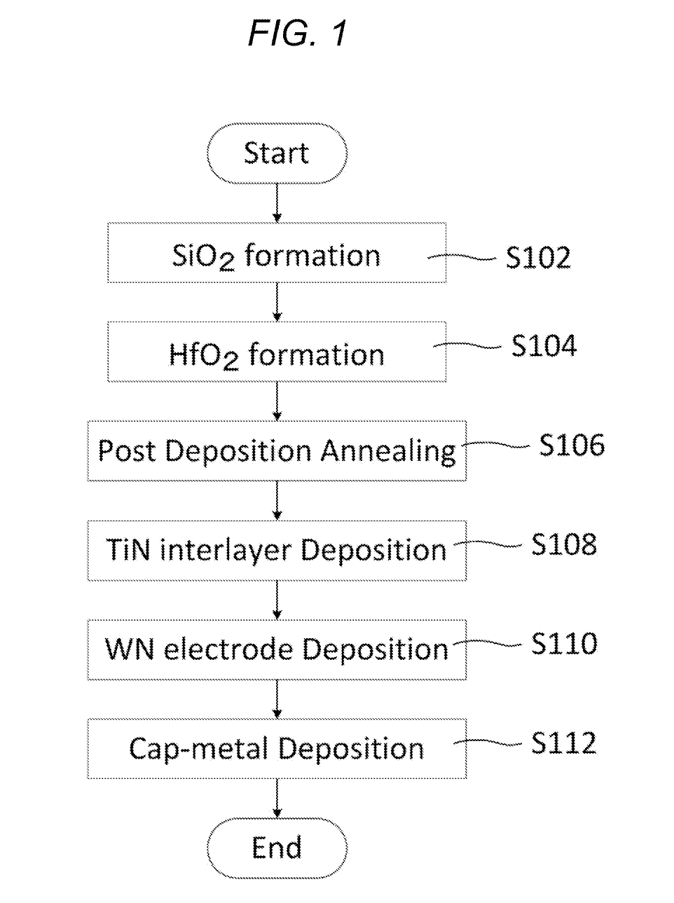

Next, a description will be given below of a method of manufacturing a MOSFET in a preferred embodiment of the present invention, with reference to FIG. 1.

First, a silicon oxide film (SiO₂ film) 31 is formed, as a silicon-based insulating film, on a principal surface 11 of a Si substrate 10 by means of thermal oxidation (Step S102). The SiO₂ film 31 is formed as an interface layer at the interface between the Si substrate 10 and an HfO₂ film 32 that serves as a high dielectric constant insulating film and will be sequentially formed thereon. The SiO₂ film 31 forms a part of the gate insulating film 30.

More specifically, for example, an oxidizing furnace may be used. The Si substrate 10 is placed within the processing chamber of the oxidizing furnace, and then O₂ gas or some other oxidizing gas is supplied to the interior of the processing chamber. As a result of subjecting the Si substrate 10 to thermal oxidation (dry oxidation), the SiO₂ film 31 is formed on the principal surface 11 of the Si substrate 10 as the interface layer. Exemplary processing conditions are as follows.

Temperature of Si substrate 10: 850 to 1000° C.

Pressure in processing chamber: 1 to 1000 Pa

Flow rate of O₂ gas supplied: 10 to 1000 sccm

Thickness of SiO₂ film 31: 0.4 to 1.5 nm

Instead of the dry oxidation, for example, wet oxidation, decompression oxidation, or plasma oxidation may be performed to form the SiO₂ film 31.

The hafnium oxide film (HfO₂ film) 32 is subsequently formed on the SiO₂ film 31 as a high dielectric constant insulating film (High-k film) (Step S104). The HfO₂ film 32 is formed thereon as the gate insulating film 30.

More specifically, the Si substrate 10 on which the SiO₂ film 31 has been formed is placed within, for example, the processing chamber of a film forming furnace. Then, TDMAH gas and O₃ gas are supplied alternately to the interior of the processing chamber. A cycle of supplying TDMAH gas, purging the gas with N₂ gas, supplying O₃ gas, and purging the gas with N₂ gas is performed a predetermined number of times. As a result, the HfO₂ film 32 is formed on the SiO₂ film 31 as a gate insulating film. Exemplary processing conditions are as follows.

Temperature of Si substrate 10: 100 to 400° C.

Pressure in processing chamber: 1 to 2000 Pa

Flow rate of TDMAH gas supplied: 10 to 2000 sccm

Flow rate of O₃ gas supplied: 10 to 2000 sccm

Flow rate of N₂ gas supplied: 10 to 10000 sccm

Thickness of HfO₂ film 32: 0.9 to 4 nm

Examples of Hf-containing materials include: organic materials, such as tetrakis(dimethylamino) hafnium (Hf[N(CH₃)₂]₄, abbreviated as TDMAH), tetrakis(ethylmethylamino)hafnium (Hf[N(C₂H₅)(CH₃)]₄, abbreviated as TEMAH), and tetrakis(diethylamino)hafnium (Hf[N(C₂H₅)₂]₄, abbreviated as TDEAH); and inorganic materials, such as hafnium tetrachloride (HfCl₄). Examples of oxidants include O₃ gas and other oxidative gases (oxygen-containing gas) such as H₂O gas. Examples of purge gases (inert gases) include N₂ gas and rare gases such as Ar, He, Ne, and Xe gases. When a liquid material that is in a liquid form under an ordinary temperature and pressure, such as TDMAH, is used, it needs to be vaporized by a vaporization system such as a vaporizer or a bubbler, and supplied as a material gas.

After the formation of the HfO₂ film 32, post deposition annealing (PDA) is performed (Step S106). More specifically, for example, a thermal processing furnace (e.g., rapid thermal process (RTP) apparatus) may be used. The Si substrate 10 on which the HfO₂ film 32 has been formed is placed within the processing chamber of the RTP apparatus. Then, N₂ gas is supplied to the interior of the processing chamber, annealing the HfO₂ film 32. This PDA is performed in order to remove impurities from the HfO₂ film 32 and densify or crystallize it. Exemplary processing conditions are as follows.

Temperature of silicon substrate 10: 400 to 800° C.

Pressure in processing chamber: 1 to 1000 Pa

Flow rate of N₂ gas supplied: 10 to 10000 sccm

Annealing time: 10 to 60 sec

A titanium nitride film (TiN film) 41, which is a first metal film or a first conductive metal-containing film, is subsequently formed, as an intermediate film, on the HfO₂ film 32 having been subjected to the PDA (Step S108). The TiN film 41 may form a part of the gate electrode. As will be described later, the TiN film is oxidized by absorbing oxygen, and a part thereof is finally changed into an insulating film such as a TiO film. The part of the TiN film which has been changed into an insulating film such as a TiO film forms a part of the gate insulating film. Alternatively, as will be described later, another part of the TiN film can be left without being changed into an insulating film, such as a TiO film. In this case, the part of the TiN film which has been left without being changed into an insulating film, such as a TiO film, forms a part of the gate electrode.

More specifically, the Si substrate 10 that has been subjected to the PDA is placed within, for example, the processing chamber of a film forming furnace. A first film-forming gas supply system for supplying a first film-forming gas supplies a first material gas, or TiCl₄ gas, to the interior of the processing chamber as a first film-forming gas. In addition, a first reaction gas supply system for supplying a first reaction gas supplies a first reaction gas, or NH₃ gas, to the interior of the processing chamber. Both gases are supplied alternately. In this case, a cycle of supplying TiCl₄ gas, purging the gas with N₂ gas, supplying NH₃ gas, and purging the gas with N₂ gas is performed a predetermined number of times. In this way, the TiN film 41 is formed on the HfO₂ film 32 having been subjected to the PDA. Exemplary processing conditions are as follows.

Temperature of silicon substrate 10: 300 to 450° C.

Pressure in processing chamber: 1 to 10000 Pa

Flow rate of TiCl₄ gas supplied: 10 to 10000 sccm

Flow rate of NH₃ gas supplied: 10 to 50000 sccm

Flow rate of N₂ gas supply: 10 to 10000 sccm

Thickness of TiN film 41: 0.2 to 5 nm

Examples of Ti-containing materials include: inorganic materials such as titanium tetrachloride (TiCl₄); and organic materials such as tetrakis(ethylmethylamino)titanium (Ti[N(C₂H₅) (CH₃)]₄, abbreviated as TEMAT), tetrakis(dimethylamino)titanium (Ti[N(CH₃)₂]₄, abbreviated as TDMAT), and tetrakis(diethylamido)titanium (Ti[N(C₂H₅)₂]₄, abbreviated as TDEAT). Examples of nitriding agents include nitriding gases (nitrogen-containing gases) such as ammonia gas (NH₃) gas, diazene gas (N₂H₂) gas, hydrazine gas (N₂H₄) gas, and N₃H₈ gas. Examples of purge gases (inert gases) include N₂ gas and rare gases such as Ar, He, Ne, and Xe gases. When a liquid material, such as TiCl₄, that is in a liquid form at an ordinary temperature and pressure is used, it needs to be vaporized by a vaporization system such as a vaporizer or a bubbler, and supplied as a material gas.

A tungsten nitride film (WN film) 43, which is a second metal film or a second conductive metal-containing film, is formed on the TiN film 41 as the gate electrode (Step S110). Since both the TiN film 41 and the WN film 43 can be formed under the same condition, they are preferably formed sequentially in situ within the same processing chamber, although they can be formed separately in different film-forming apparatuses or processing chambers.

More specifically, the silicon substrate 10 on which the TiN film 41 has been formed is placed within, for example, the processing chamber of a film forming furnace. A second reaction gas supply system supplies a second reaction gas, or diborane (B₂H₆) gas, to the interior of the processing chamber. In addition, a second film-forming gas supply system supplies a second material gas, or tungsten hexafluoride (WF₆) gas, as a second film-forming gas and NH₃ gas to the interior of processing chamber. The B₂H₆ gas, WF₆ gas, and NH₃ gas are supplied alternately. In this case, a cycle of supplying B₂H₆ gas, purging the gas with N₂ gas purge, supplying WF₆ gas, purging the gas with N₂ gas, supplying NH₃ gas, and purging the gas with N₂ gas is performed a predetermined number of times. In this way, the WN film 43 is formed. It should be noted that both the TiN film 41 and the WN film 43 are sequentially formed in-situ within the same processing chamber. Exemplary processing conditions are as follows.

Temperature of Si substrate 10: 300 to 450° C.

Pressure in processing chamber: 1 to 10000 Pa

Flow rate of B₂H₆ gas supplied: 10 to 50000 sccm

Flow rate of WF₆ gas supplied: 10 to 10000 sccm

Flow rate of NH₃ gas supplied: 1 to 2000 sccm

Flow rate of N₂ gas supplied: 10 to 10000 sccm

Thickness of WN film 43: 1 to 10 nm

Instead of the B₂H₆ gas, Si₂H₆ or SiH₄ gas may be used to form the WN film 43 as a reducing agent (reducing gas).

A cap-metal (not illustrated) is subsequently formed on the WN film 43 (Step S112). In this way, a MOSFET having a structure in a preferred embodiment of the present invention is manufactured.

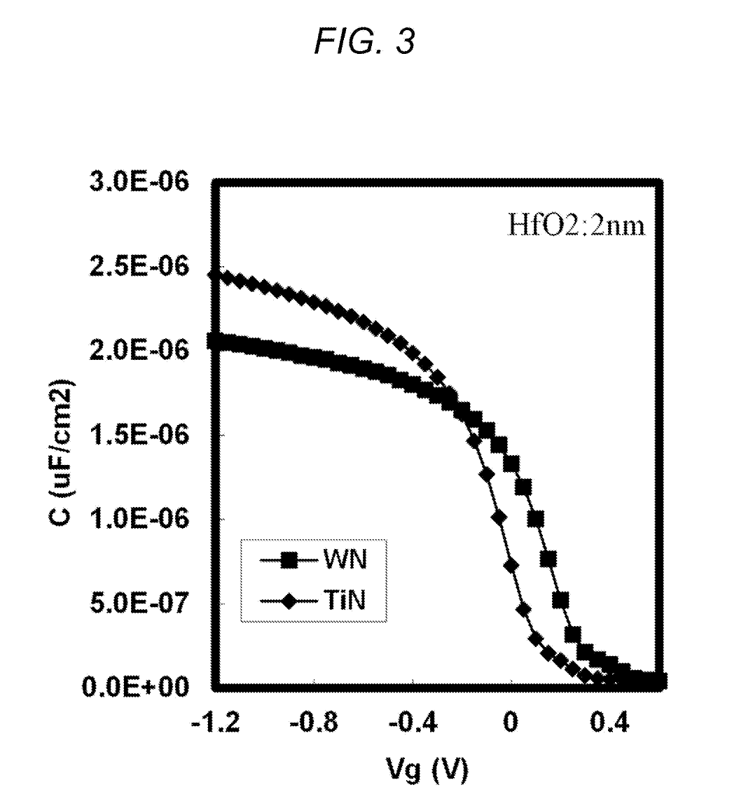

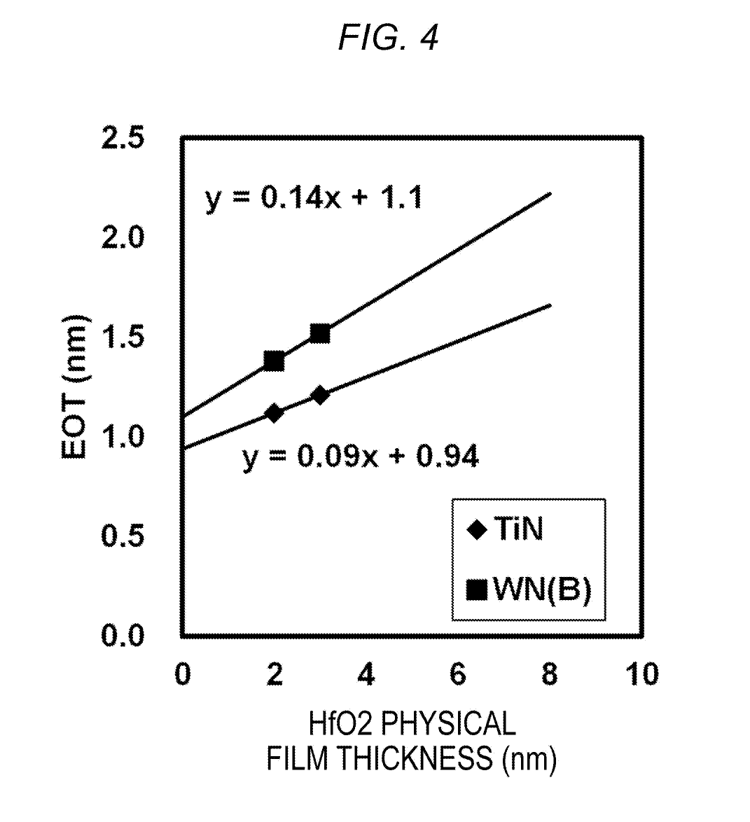

A description will be given of results of experiments related to the technology of the present invention which the inventor made. The present invention was made based on these experimental results. With reference to FIGS. 3 and 4, the relationship between the oxidative tendency of a metal film and the capacitor characteristic thereof will be described. FIGS. 3 and 4 each show the result of evaluating the characteristics of two MOSFETs. One of the MOSFETs has a gate electrode formed of a TiN film and an HfO₂ film as a gate insulating film (referred to below as a “first sample” as appropriate), whereas the other of the MOSFETs has a gate electrode formed of a WN film and an HfO₂ film as a gate insulating film (referred to below as a “second sample” as appropriate).

In FIG. 3, the CV curves of both samples are drawn; the diamond-shaped symbols (♦) denote the first sample, or more specifically a MOSFET having an electrode formed of a 5 nm TiN film, and the square symbols (▪) denote the second sample, or more specifically a MOSFET having an electrode formed of a 5 nm WN film. The vertical axis represents a capacitance; the lateral axis represents a gate voltage. As a CV curve for a MOSFET is displaced toward the positive side, its work function increases. As can be seen from FIG. 3, the CV curve for the second sample is displaced more greatly toward the positive side than that for the first sample. This demonstrates that the MOSFET with an electrode formed of a WN film exhibits a higher work function than that with an electrode formed of a TiN film.

FIG. 4 shows the relationship between the physical film thicknesses of the HfO₂ films and the EOTs thereof; the diamond-shaped symbols (♦) denote the first sample and the square symbols (▪) denote the second sample. The vertical axis represents an EOT; the lateral axis represents a physical film thickness of HfO₂. In FIG. 4, the y intercept indicates the capacitive component of a part other than a gate insulating film; the reciprocal of the inclination indicates the dielectric constant of the gate insulating film. As can be seen from FIG. 4, the straight line for the second sample exhibits a larger inclination and y intercept than that for the first sample. This demonstrates that the MOSFET with an electrode formed of a WN film has a gate insulating film with a smaller dielectric constant than the MOSFET with an electrode formed of a TiN film. Moreover, the MOSFET having an electrode formed of a WN film has a part other than the gate insulating film which exhibits a greater capacitive component than the MOSFET with an electrode formed of a TiN film.

The reason why the first sample exhibits a higher dielectric constant than the second sample could be that the oxygen defect rate of the gate insulating film in the first sample is higher. The reason why the second sample has a part other than the gate insulating film which exhibits a greater capacitive component than the first sample could be that another insulating film is formed in the first sample in addition to the HfO₂ film. The reason why the second sample exhibits a larger y intercept than the first sample could be that an insulating film with a high dielectric constant is formed in the first sample.

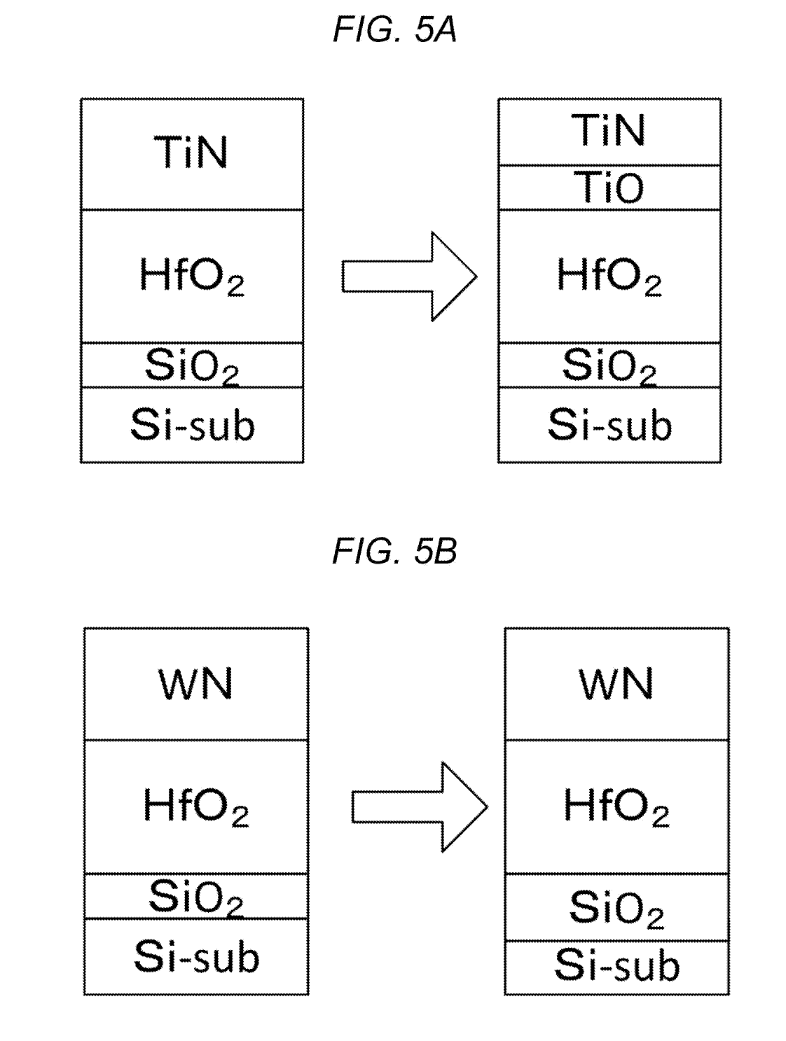

As illustrated in FIG. 5A, when a TiN film is formed in a MOSFET as an electrode, oxygen contained in the gate insulating film could diffuse and be captured by the TiN film. Then, the TiN film could be oxidized to form a TiO film with a high dielectric constant. As illustrated in FIG. 5B, when a WN film is formed in a MOSFET as an electrode, the Si substrate could be oxidized instead of the WN film. Then, a SiO film with a lower dielectric constant than the TiO film could be formed. In short, when the electrode is formed of a TiN film, the TiN film is oxidized, because it is more susceptible to oxidation than the Si substrate. When the electrode is formed of a WN film, the Si substrate is oxidized, because it is more susceptible to oxidation than the WN film. For the sake of convenience, hereinafter the oxidative tendency can be indicated by inequality signs. For example, WN<Si<TiN means that TiN is more susceptible to oxidation than Si and Si is more susceptible to oxidation than WN.

It can be found from the above that the flat band voltage Vfb can be displaced more greatly toward the positive side when an electrode is formed of a WN film or some other film that is resistant to oxidation and has a high work function than when an electrode is formed of a TiN film as in a related art. However, this disadvantageously causes the oxidation of the Si substrate, increasing the EOT. In this case, the increase in the EOT is approximately 0.26 to 0.3 nm, which is nearly equal to the thickness of one atomic layer (0.2 to 0.3 nm) when converted into the thickness of a SiO₂ film.

As a result of diligent studies of above, the inventor has reached a conclusion that interposing an intermediate film, as an electrode, that is susceptible to oxidation and getters oxygen corresponding to the increase in the EOT between a metal film and a high dielectric constant insulating film can reduce the increase in the EOT which would be caused by the oxidation of the Si substrate. In this case, it is possible to obtain a high work function by forming an electrode with a WN film or some other metal film having a high work function.

Consequently, the gate electrode, or the WN film 43, is formed of a metal film which is more resistant to oxidation than the Si substrate 10 (WN<Si); the intermediate film, or the TiN film 41, is formed of a metal film which is more susceptible to oxidation than the Si substrate 10 (Si<TiN). This configuration can prevent extra oxygen contained in the gate insulating film 30 and external oxygen that has passed through the WN film 43 from moving to the Si substrate 10. More specifically, the TiN film 41 that is more susceptible to oxidation than the Si substrate 10 getters extra oxygen contained in the gate insulating film 30 and externally incoming oxygen, preventing the oxidation of the Si substrate 10. The TiN film 41 that has gettered the oxygen is oxidized, thereby changed into a TiO film with a high dielectric constant.

When the intermediate film, or the TiN film 41, is formed with an insufficient thickness, it may fail to sufficiently getter oxygen contained in the gate insulating film 30 and externally incoming oxygen having passed through the WN film 43. In which case, a part of the extra oxygen that has not been gettered might oxidize the Si substrate 10. When the thickness of the TiN film 41 is greater than the increase in the EOT, the TiN film 41 can sufficiently getter oxygen, thereby reducing the oxidation of the Si substrate 10.

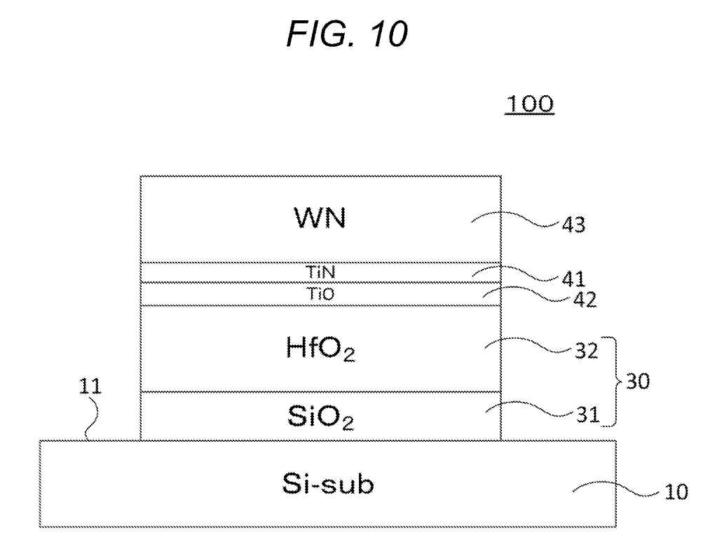

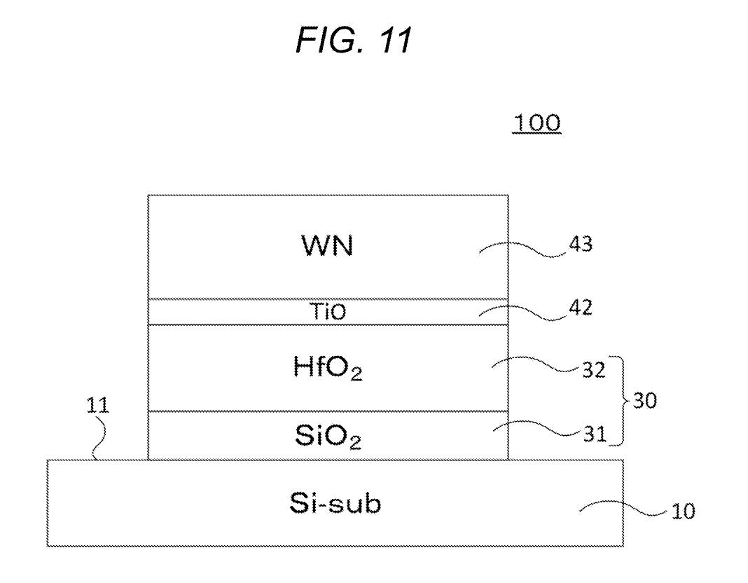

When the thickness of the TiN film 41 is set in the range of from 0.2 to 5 nm inclusive that corresponds to the increase in the EOT, for example, the TiN film 41 can sufficiently reduce the oxidation of the Si substrate 10. When the thickness of the TiN film 41 is set to 0.2 nm or below, it may fail to sufficiently getter oxygen. For this reason, in order to sufficiently getter oxygen, the thickness of the TiN film 41 needs to be set to equal to or larger than that of one atomic layer (0.2 nm). When the thickness of the TiN film 41 exceeds 5 nm, a part of the TiN film 41 may be left unoxidized to form a part of the gate electrode (see FIG. 10), influencing the work function of the WN film 43. Consequently, the thickness of the TiN film 41 needs to be set to 5 nm or below. When the thickness of the TiN film. 41 is 3 nm or below, the influence that the TiN film. 41 exerts upon the work function of the WN film 43 is sufficiently reduced. When the thickness of the TiN film 41 is 0.6 nm or below, the entire TiN film 41 is changed into a TiO film 42 (see FIG. 11) that is an insulating film, reducing an influence on the work function of the WN film 43. Here, the expression “the thickness of a film is set such that it can sufficiently getter oxygen contained in the gate insulating film 30 and externally incoming oxygen having passed through the WN film 43” can be interpreted as “the thickness of a film is set such that a metal content therein becomes large enough to getter the oxygen.”

Consequently, the thickness of the TiN film 41 is set in the range of from 0.2 to 5 nm inclusive, more preferably from 0.2 to 3 nm, or even more preferably from 0.2 to 0.6 nm.

As illustrated in FIG. 10, by changing a part of the intermediate film, or the TiN film 41, into an insulating film, or the TiO film 42, and leaving the remaining part thereof as it is, the work function of the gate electrode can be controlled (tuned). This is because that the work function of the gate electrode is dependent on both the WN film 43 and the TiN film 41 left unoxidized. In this case, the TiN film 41 left unoxidized functions as a part of the gate electrode. Therefore, by controlling the thickness of the unoxidized TiN film 41 that forms a part of the gate electrode, the work function of the gate electrode can be controlled. As the thickness of the unoxidized TiN film 41 increases, the work function decreases.

In the preferred embodiment of the present invention, a SiO₂ film is formed as a silicon-based insulating film that serves as an interface layer between a Si substrate and a high dielectric constant insulating film, or an HfO₂ film. Instead of this SiO₂ film, however, a silicon oxynitride film (SiON film) may be formed. Furthermore, an HfO₂ film is formed as a high dielectric constant gate insulating film. Instead of this HfO₂ film, however, a zirconium oxide film (ZrO₂ film), a titanium oxide film (TiO₂ film), a niobium oxide film (Nb₂O₅ film), a tantalum oxide film (Ta₂O₅ film), a hafnium silicate film (HfSiOₓ film), a zirconium silicate film (ZrSiOₓ film), a hafnium aluminate film (HfAlOₓ film), a zirconium aluminate film (ZrAlOₓ film), a combination thereof, or a mixture thereof may be formed.

In the embodiment described above, a TiN film which is a conductive metal film is formed as an intermediate film 40. Instead of this TiN film, a conductive metal film such as a tantalum nitride film (TaN film), a niobium nitride film (NbN), a hafnium nitride film (HfN film), a zirconium nitride film (ZrN), or a tungsten film (W film) may be formed. An insulating film such as an AlN film may be formed.

A metal-containing film that is a metal film 50 which forms a gate electrode and is resistant to oxidation may be, in addition to a WN film, a metal film containing at least one of nitrogen, oxygen, or carbon. Examples of such metal films include an MoN film, a NiN film, a CoN film, a WC film, an MoC film, a NiC film, a CoC film, a WCN film, an MoCN film, a NiCN film, a CoCN film, a WO film, an MoO film, a NiO film, a CoO film, a WON film, an MoON film, a NiON film, and a CoON film.

The term “metal film” herein refers to a film made of a conductive material containing metal atoms, that is, a conductive metal-containing film. Examples of such metal films include a conductive elemental metal film made of an elemental metal, a conductive metallic nitride film, a conductive metal oxide film, a conductive metallic nitride oxide film, a conductive metal carbide film, a conductive metallic carbonitride film, a conductive metallic composite film, a conductive metallic alloy film, and a conductive metallic silicide film. Here, a WN film and a TiN film formed as an intermediate film are conductive metallic nitride films.

The expression “an element is more resistant to oxidation” refers to “an element has a higher positive standard reduction potential.” It can also be said that “an element has a stronger ionization tendency” or “an element is less likely to be bonded to oxygen atoms.” The expression “element A is more susceptible to oxidation than element B” refers to “element A is oxidized more than element B when they are oxidized under the same condition.”

This embodiment produces one or more effects described below.

(1) An intermediate film is interposed between a gate electrode formed of a metal film and an insulating film having a high dielectric constant. This intermediate film getters oxygen diffusing from the insulating film and external oxygen coming from the metal film, reducing the oxidation of the Si substrate. It is therefore possible to reduce the increase in the EOT and allows the electrode to be formed of a metal film having a high work function.
(2) Controlling the oxidation of an intermediate film can tune the work function of the electrode to a desired value. By controlling the oxidation of the intermediate film in such a way that a part of the intermediate film is changed into an insulating film and a remaining part thereof is left unoxidized to function as a part of the electrode, the work function of the electrode can be controlled.
(3) A substrate can be sequentially manufactured in-situ within the same processing chamber. This prevents an intermediate film in the substrate from being naturally oxidized. A metal film is formed as the electrode while the intermediate film is kept unoxidized, whereby the intermediate film can sufficiently getter oxygen.

One or more of Steps S102 to S112 in the embodiment described above may be performed sequentially using a cluster apparatus or some other substrate processing system.

For example, Steps S102 and S104 may be performed sequentially using a cluster apparatus. Steps S102 to S106 may be performed sequentially using a cluster apparatus. Steps S102 to S108 may be performed sequentially using a cluster apparatus. Steps S102 to S110 may be performed sequentially using a cluster apparatus. Steps S102 to S112 may be performed sequentially using a cluster apparatus.

For example, Steps S106 and S108 may be performed sequentially using a cluster apparatus. Steps S106 to S110 may be performed sequentially using a cluster apparatus. Steps S106 to S112 may be performed sequentially using a cluster apparatus. Steps S104 to S112 may be performed sequentially using a cluster apparatus.

For example, Steps S108 and S110 may be performed sequentially using a cluster apparatus. Steps S108 to S112 may be performed sequentially using a cluster apparatus.

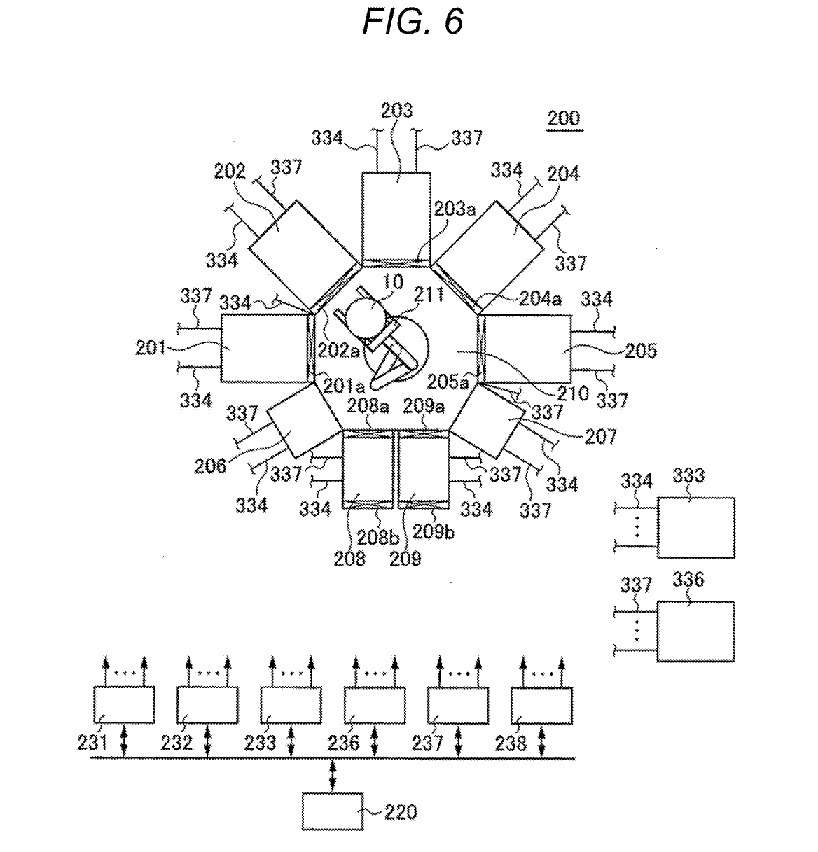

When all of Steps S102 to S112 are performed sequentially, for example, a cluster apparatus 200 as illustrated in FIG. 6 can be used.

The cluster apparatus 200, which acts as a substrate processing system, includes processing chambers 201, 202, 203, 204, and 205 as processing sections that treat a Si substrate 10. A loading chamber 208 carries the Si substrate 10 into the cluster apparatus 200. An unloading chamber 209 carries the Si substrate 10 from the cluster apparatus 200. The cooling chambers 206 and 207 cool the Si substrate 10. These processing chambers 201, 202, 203, 204, and 205, loading chamber 208, unloading chamber 209, and cooling chambers 206 and 207 are all attached to a transfer chamber 210. This transfer chamber 210 is provided with a transfer machine 211 that carries the Si substrate 10 from one of the above chambers to another. A gate valve 201a is installed between the transfer chamber 210 and the processing chamber 201. A gate valve 202a is installed between the transfer chamber 210 and the processing chamber 202. A gate valve 203a is installed between the transfer chamber 210 and the processing chamber 203. A gate valve 204a is installed between the transfer chamber 210 and the processing chamber 204. A gate valve 205a is installed between the transfer chamber 210 and the processing chamber 205. The loading chamber 208 is provided with gate valves 208a and 208b on its opposite sides. The unloading chamber 209 is provided with gate valves 209a and 209b on its opposite sides.

The cluster apparatus 200 further includes a gas supply system 333 and an exhaust system 336. The gas supply system 333 supplies a processing gas or an inert gas to the interiors of the processing chambers 201, 202, 203, 204, and 205 through gas piping 334. Also, the gas supply system 333 supplies an inert gas to the interiors of the transfer chamber 210, the loading chamber 208, the unloading chamber 209, and the cooling chambers 206 and 207 through the gas piping 334. The exhaust system 336 discharges gas from the interiors of the processing chambers 201, 202, 203, 204, and 205, the transfer chamber 210, the loading chamber 208, the unloading chamber 209, and cooling chambers 206 and 207 through exhaust piping 337.

As illustrated in FIG. 6, the cluster apparatus 200 further includes a gate valve control unit 231, a transfer machine control unit 232, a gas supply system control unit 233, an exhaust system control unit 236, a temperature control unit 237, and a pressure control unit 238. The gate valve control unit 231 controls the open/close operations of the gate valves 201a, 202a, 203a, 204a, 205a, 208a, 209a, 208b, and 209b. The transfer machine control unit 232 controls the operation of the transfer machine 211. The gas supply system control unit 233 controls the gas supply system 333. The exhaust system control unit 236 controls the exhaust system 336. The temperature control unit 237 controls the temperatures inside the processing chambers 201, 202, 203, 204, and 205. The pressure control unit 238 controls the pressure inside the processing chambers 201, 202, 203, 204, and 205, the transfer chamber 210, the loading chamber 208, the unloading chamber 209, and the cooling chambers 206 and 207. As illustrated in FIG. 6, the cluster apparatus 200 further includes a controller 220, which will be described in detail later.

The cluster apparatus 200 treats the Si substrate 10 in the following manner, for example.

First, the gate valve 208b is opened, and the Si substrate (wafer) 10 is carried into the loading chamber (load lock chamber) 208, which is a transfer spare chamber. Then, the gate valve 208b is closed, and the loading chamber 208 is vacuum-exhausted. After the pressure inside the loading chamber 208 has reached a predetermined value, the gate valve 208a is opened. In this case, the transfer chamber 210 has already been vacuum-exhausted and maintained at a predetermined pressure.

After the gate valve 208a has been opened, the wafer transfer machine 211 picks up the wafer 10 in the loading chamber 208 and carry it into the transfer chamber 210. The gate valve 208a is subsequently closed and then the gate valve 201a is opened. The wafer transfer machine 211 carries the wafer 10 in the transfer chamber 210 into the first processing chamber 201. The gate valve 201a is closed, after which a process through which a SiO₂ film is formed on the wafer 10 is performed within the processing chamber 201 (Step S102).

The gate valve 201a is opened, and then the wafer transfer machine 211 picks up the wafer 10 on which the SiO₂ film has been formed in the processing chamber 201, and carries it into the transfer chamber 210. The gate valve 201a is subsequently closed, and then the gate valve 202a is opened. The wafer transfer machine 211 carries the wafer 10 on which the SiO₂ film has been formed in the transfer chamber 210 into the processing chamber 202. The gate valve 202a is closed, after which a process through which an HfO₂ film is formed on the SiO₂ film of the wafer 10 is performed within the processing chamber 202 (Step S104).

The gate valve 202a is opened, and then the wafer transfer machine 211 picks up the wafer 10 on which the HfO₂ film has been formed in the processing chamber 202, and carries it into the transfer chamber 210. The gate valve 202a is subsequently closed, and then the gate valve 203a is opened. The wafer transfer machine 211 carries the wafer 10 on which the HfO₂ film has been formed in the transfer chamber 210 into the processing chamber 203. The gate valve 203a is closed, after which the HfO₂ film on the wafer 10 is subjected to PDA within the processing chamber 203 (Step S106).

The gate valve 203a is opened, and then the wafer transfer machine 211 picks up the wafer 10 that has been subjected to the PDA in the processing chamber 203, and carries it into the transfer chamber 210. The gate valve 203a is closed, and then the gate valve 204a is opened. The wafer transfer machine 211 carries the wafer 10 that has been subjected to the PDA in the transfer chamber 210 into the processing chamber 204. The gate valve 204a is closed, after which a process through which a TiN film is formed on the HfO₂ film of the wafer 10 which has been subjected to the PDA and a process through which a WN film is formed on the TiN film are performed sequentially in-situ within the processing chamber 204 (Steps S108 and S110).

More specifically, a first film-forming gas supply system supplies a first material gas, or TiCl₄ gas, to the interior of the processing chamber 204 as a first film-forming gas. In addition, a first reaction gas supply system supplies a first reaction gas, or NH₃ gas, to the interior of the processing chamber 204. Both gases are supplied alternately. In this case, a cycle of supplying TiCl₄ gas, purging the gas with N₂ gas, supplying NH₃ gas, and purging the gas with N₂ gas is performed a predetermined number of times. In this way, the TiN film is formed on the HfO₂ film of the wafer 10 which has been subjected to the PDA. Following this, a second reaction gas supply system supplies a second reaction gas, or diborane (B₂H₆) gas, to the interior of the processing chamber 204. In addition, a second film-forming gas supply system supplies a second material gas, or tungsten hexafluoride (WF₆) gas, as a second film-forming gas and NH₃ gas to the interior of the processing chamber 204. The B₂H₆ gas, WF₆ gas, and NH₃ gas are supplied alternately. In this case, a cycle of supplying B₂H₆ gas, purging the gas with N₂ gas purge, supplying WF₆ gas, purging the gas with N₂ gas, supplying NH₃ gas, and purging the gas with N₂ gas is performed a predetermined number of times. In this way, the WN film is formed. It should be noted that the first and second film-forming gas supply systems and the first and second reaction gas supply systems are included in the gas supply system 333.

The gate valve 204a is subsequently opened, and then the wafer transfer machine 211 picks up the wafer 10 on which both the TiN and WN films are formed in the processing chamber 204, and carries it into the transfer chamber 210. The gate valve 204a is closed, and then the gate valve 205a is opened. The wafer transfer machine 211 carries the wafer 10 on which both the TiN and WN films are formed in the transfer chamber 210 into the processing chamber 205. The gate valve 205a is closed, after which a process through which a cap-metal is formed on the WN film (see FIG. 1) of the wafer 10 is performed within the processing chamber 205 (Step S112).

The gate valve 205a is opened, and then the wafer transfer machine 211 picks up the wafer 10 on which the cap-metal is formed in the processing chamber 205, and carries it into the transfer chamber 210. The gate valve 205a is closed, and then the gate valve 209a is opened. Following this, the wafer transfer machine 211 carries the wafer 10 that has been subjected to a series of processes, or Steps S102 to S112, in the transfer chamber 210 into the unloading chamber (load lock chamber) 209, which is a transfer spare chamber. After the wafer 10 has been carried, the gate valve 209a is closed. The pressure inside the unloading chamber 209 is returned to the atmospheric pressure. Then, the gate valve 209b is opened, and the wafer 10 that has been subjected to the series of processes is taken out.

After the above steps have been performed, the wafer 10 may optionally be carried into the cooling chamber 206 or 207 and cooled. In this case, the wafer 10 is kept within the cooling chamber 206 or 207 until the internal temperature has reached a predetermined value. Furthermore, the wafer 10 may be cooled to the predetermined temperature, and carried into the processing chamber in which a next step will be performed or carried into the unloading chamber 209 and taken out therefrom.

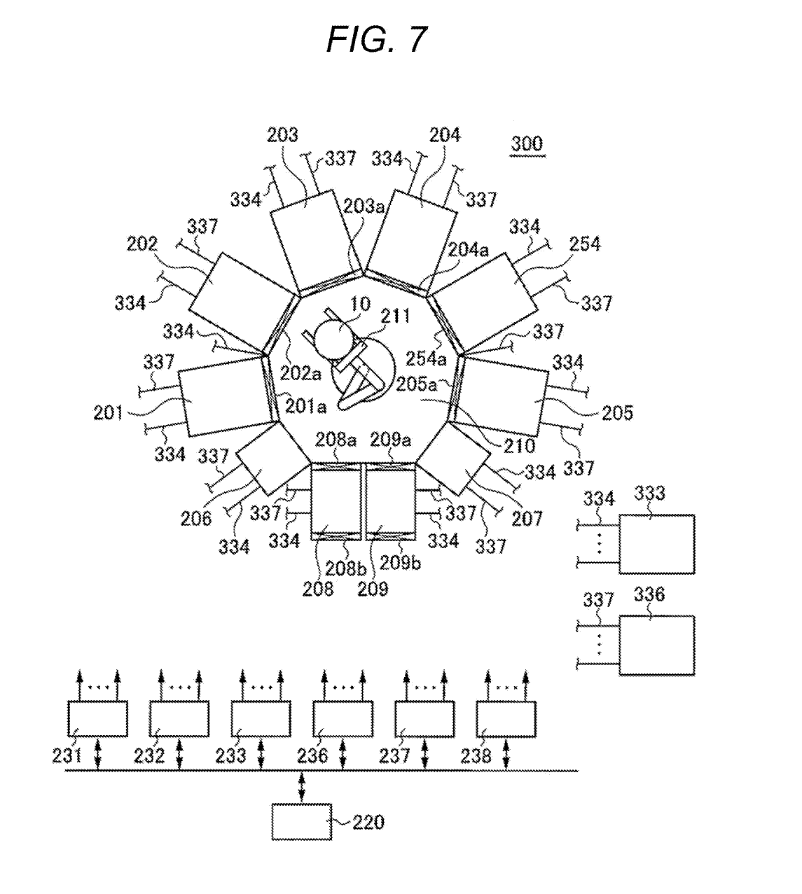

Next, a description will be given of another exemplary cluster apparatus that sequentially performs all Steps S102 to S112, with reference to FIG. 7. The cluster apparatus 200 illustrated in FIG. 6 includes five processing chambers 201, 202, 203, 204, and 205. Unlike this, however, a cluster apparatus 300 illustrated in FIG. 7 includes six processing chambers 201, 202, 203, 204, 254, and 205. Other components of the cluster apparatus 300 are identical to those of the cluster apparatus 200.

As illustrated in FIG. 7, the cluster apparatus 300 has a gate valve 254a between a transfer chamber 210 and the processing chamber 254. A gas supply system 333 supplies a processing gas or an inert gas to the interior of this processing chamber 254 through gas piping 334. An exhaust system 336 discharges gas from the interior of the processing chamber 254 through exhaust piping 337. A gate valve control unit 231 controls the open/close operation of the gate valve 254a. A temperature control unit 237 controls the temperature inside the processing chamber 254. A pressure control unit 238 controls the pressure inside the processing chamber 254.

In the cluster apparatus 200 of FIG. 6, processes of forming a TiN film and a WN film are performed sequentially within the processing chamber 204. In contrast, in the cluster apparatus 300 of FIG. 7, a process of forming a TiN film is performed within the processing chamber 204 and a process of forming a WN film is performed within the processing chamber 254.

The processes described above are performed sequentially by individual units in each of the cluster apparatuses 200 and 300 under the control of the controller 220. For example, the cluster apparatus 300 may have a plurality of controllers, and different controllers may individually control the processes performed within the processing chambers 204 and 254.

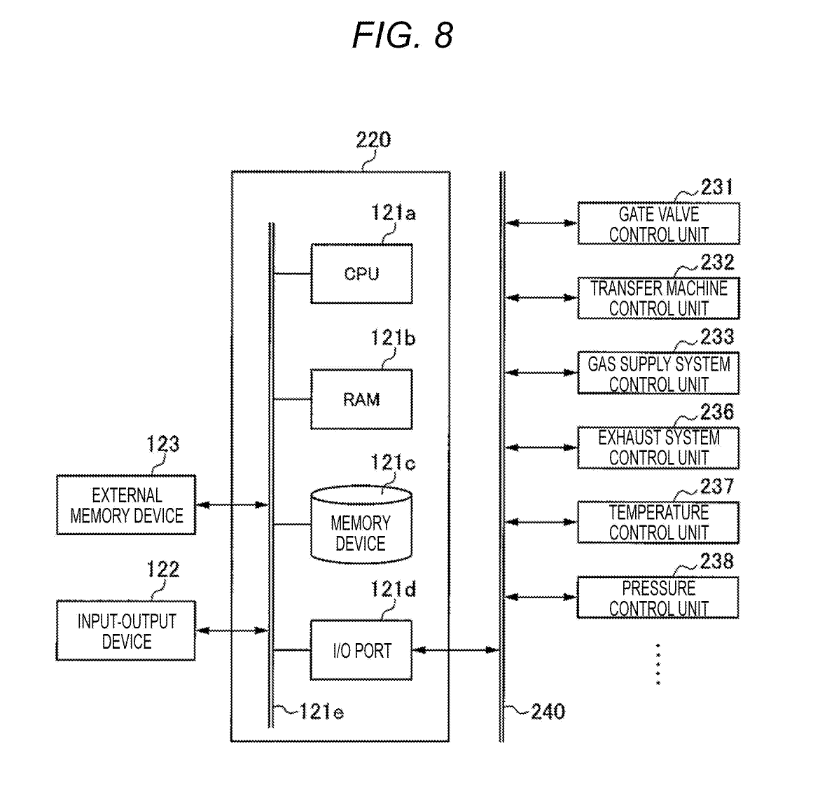

As illustrated in FIG. 8, the controller 220, which is configured with the above control units, may be implemented using a computer that includes a central processing unit (CPU) 121a, a random access memory (RAM) 121b, a memory device 121c, and an I/O port 121d. Each of the RAM 121b, the memory device 121c, and the I/O port 121d exchanges data with the CPU 121a via an internal bus 121e. The controller 220 is connected to an input-output device 122 that may be implemented using, for example, a touch panel.

The memory device 121c may be implemented using, for example, a flash memory or a hard disk drive (HDD). This memory device 121c stores in a computer readable manner, for example, a control program for use in controlling the operation of the cluster apparatus 200 and a process recipe in which the procedures and conditions for a series of wafer processes as described above are described. A process recipe functions as a program and contains procedures (processing steps) for a series of wafer processes as described above which the controller 220 is to execute in order to yield a predetermined result. A combination of a process recipe and a control program can be collectively referred to below as a program. The word “program” herein refers to a process recipe alone, a control program alone, or a combination thereof. The RAM 121b serves as a memory region (work area) in which a program or data read by the CPU 121a is temporarily retained.

The I/O port 121d is connected, via a bus 240, to the above gate valve control unit 231, the transfer machine control unit 232, the gas supply system control unit 233, the exhaust system control unit 236, the temperature control unit 237, the pressure control unit 238, and other units.

The CPU 121a reads a control program from the memory device 121c and executes it. Also, the CPU 121a reads a process recipe from the memory device 121c in response to, for example, the input of an operation command from the input-output device 122. Then, the CPU 121a controls the gate valve control unit 231, the transfer machine control unit 232, the gas supply system control unit 233, the exhaust system control unit 236, the temperature control unit 237, the pressure control unit 238, and other control units in accordance with the contents of the process recipe, thereby controlling, for example, the operations of heaters (not illustrated) that heat the gate valves 201a, 202a, 203a, 204a, 254a, 205a, 208a, 209a, 208b, and 209b, the transfer machine 211, the gas supply system 333, the exhaust system 336, the processing chambers 201, 202, 203, 204, 254, and 205.

The controller 220 may be implemented using either a special-purpose computer or a general-purpose computer. For example, the controller 220 in this embodiment may be implemented using a general-purpose computer in which the above program is installed via an external memory device 123. Examples of such external memory devices include: magnetic disks such as magnetic tapes, flexible disks, and hard disks; optical discs such as CDs and DVDs; magneto-optical discs such as MO discs; and semiconductor memories such as USB memories and memory cards. It should be noted that a method of applying a program to a computer is not limited to that using the external memory device 123. Instead of using the external memory device 123, for example, a method of applying a computer may use a communication network such as the Internet or a dedicated line. The memory device 121c and the external memory device 123 may be referred to as non-transitory computer-readable recording media. Alternatively, they may be collectively referred to below as non-transitory computer-readable recording media. The word “non-transitory computer-readable recording medium” herein may refer to a memory device 121c alone, an external memory device 123 alone, and a combination thereof.

A substrate processing system that performs a series of processing steps may include a plurality of stand-alone apparatuses that individually perform the processing steps, instead of a cluster apparatus. The foregoing embodiments and their exemplary examples may be performed in combination as appropriate.

To achieve one embodiment of the present invention, a process recipe stored in an existing substrate processing system may be changed or modified. For that purpose, a process recipe conforming to an embodiment of the present invention may be installed in an existing substrate processing system via a telecommunication line or a non-transitory computer-readable recording medium. Alternatively, a process recipe stored in an existing substrate processing system may be modified in conformity with an embodiment of the present invention through an operation of an input-output device in the substrate processing system.

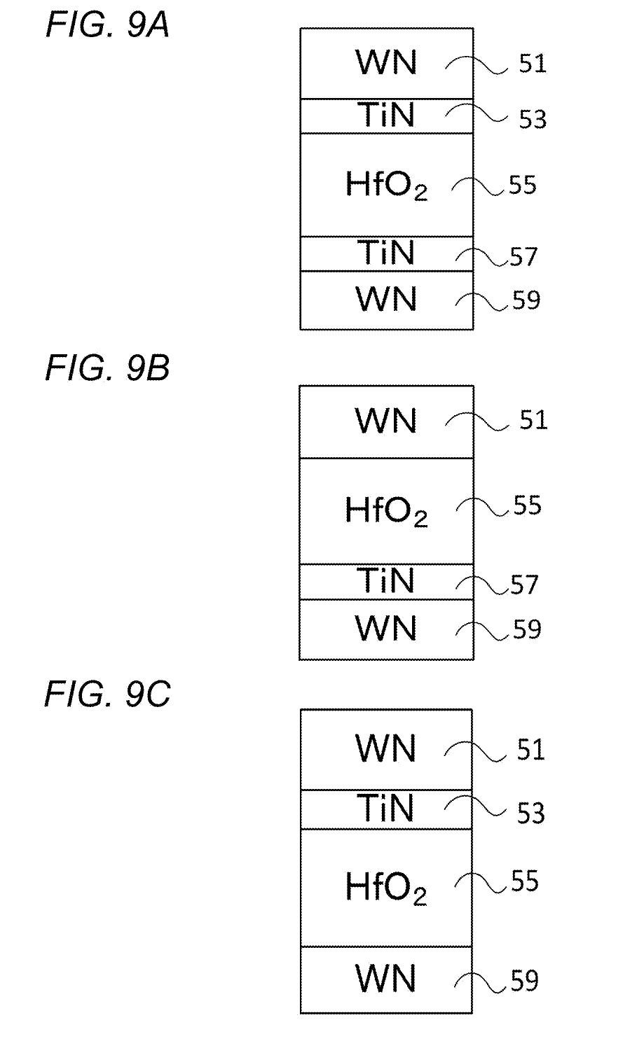

Next, a description will be given of an embodiment in which one or more intermediate films are applied to a capacitor electrode. FIGS. 9A to 9C illustrate embodiments (semiconductor devices), each of which includes: WN films as capacitor electrodes, which are metal films resistant to oxidation; one or more TiN films as intermediate films, which are metal films susceptible to oxidation; and an HfO₂ film as a capacitor insulating film.

In the embodiment of FIG. 9A, oxygen contained in an HfO₂ film 55 is gettered by TiN films 53 and 57 that are metal films susceptible to oxidation; the TiN film 53 is an intermediate film interposed between the HfO₂ film 55 and a top electrode, or a WN film 51, and the TiN film 57 is an intermediate film interposed between the HfO₂ film 55 and a bottom electrode, or a WN film 59. As a result, at least a part of each of the TiN films 53 and 57 is changed into a TiO film, which is an insulating film.

In the embodiment of FIG. 9B, oxygen contained in an HfO₂ film 55 is gettered by a TiN film 57 that is a metal film susceptible to oxidation; the TiN film 57 is an intermediate film interposed between the HfO₂ film 55 and a bottom electrode, or a WN film 59. As a result, at least a part of the TiN film 57 is changed into a TiO film, which is an insulating film.

In the embodiment of FIG. 9C, oxygen contained in an HfO₂ film 55 is gettered by a TiN film 53 that is a metal film susceptible to oxidation; the TiN film 53 is an intermediate film interposed between the HfO₂ film 55 and a top electrode, or a WN film 51. As a result, at least a part of the TiN film 53 is changed into a TiO film, which is an insulating film.

As described above, the TiN film 53 is interposed as an intermediate film between a capacitor insulating film, or the HfO₂ film 55, and a metal film acting as an electrode, or the WN film 51. In addition, the TiN film 57 is interposed as an intermediate film between the capacitor insulating film, or the HfO₂ film 55, and a metal film acting as an electrode, or the WN film 59. In this structure, oxygen contained in the capacitor insulating film, or HfO₂ film 55, moves to the intermediate films, or the TiN films 53 and 57. Consequently, the dielectric constant of the capacitor insulating film, or the HfO₂ film 55, increases.

The foregoing embodiments, their modifications, and the like can be performed in combination as appropriate. In this case, the processing conditions may be identical to those for the embodiments described above.

### Preferred Aspects of the Present Invention

The supplementary notes of preferred aspects of the present invention will be described below.

### Supplementary Note 1

According to one aspect of the present invention, there is provided a method of manufacturing a semiconductor device or a method of processing a substrate, including:

forming an intermediate film on a substrate having an insulating film formed thereon; and

forming a first metal film on the intermediate film,

the intermediate film being more susceptible to oxidation than the first metal film, the intermediate film having a smaller thickness than the first metal film.

### Supplementary Note 2

In the method according to Supplementary note 1, the intermediate film is preferably a second metal film made of a material different from the first metal film.

### Supplementary Note 3

In the method according to Supplementary notes 1 and 2, the intermediate film is preferably more susceptible to oxidation than the substrate.

### Supplementary Note 4

In the method according to Supplementary notes 1 to 3, the intermediate film preferably getters oxygen.

### Supplementary Note 5

In the method according to Supplementary notes 1 to 4, the intermediate film preferably getters oxygen diffusing from an interior of the insulating film.

### Supplementary Note 6

In the method according to Supplementary notes 1 to 5, the intermediate film preferably getters externally incoming oxygen that has passed through the first metal film.

### Supplementary Note 7

In the method according to Supplementary notes 1 to 6, the intermediate film preferably getters the oxygen, and at least a part of the intermediate film is preferably changed into an insulating film.

### Supplementary Note 8

In the method according to Supplementary notes 1 to 7, the intermediate film preferably getters the oxygen, and a part of the insulating film excluding the part changed into the insulating film is preferably left unchanged.

### Supplementary Note 9

In the method according to Supplementary notes 1 to 8, the intermediate film preferably getters the oxygen, and the entire intermediate film is preferably changed into an insulating film.

### Supplementary Note 10

In the method according to Supplementary notes 1 to 9, a thickness of the intermediate film is preferably based on a metal content that enables gettering of at least the amount of oxygen diffusing from an interior of the insulating film and the amount of oxygen that has passed through the first metal film.

### Supplementary Note 11

In the method according to Supplementary notes 1 to 10, the thickness of the intermediate film preferably ranges from 0.2 to 5 nm.

### Supplementary Note 12

In the method according to Supplementary notes 1 to 11, the intermediate film and the first metal film are preferably formed sequentially within the same apparatus.

### Supplementary Note 13

According to another aspect of the present invention, there is provided a substrate processing apparatus including:

a processing chamber configured to accommodate a substrate having an insulating film formed thereon;

a first film-forming gas supply system configured to supply a first film-forming gas to the substrate within the processing chamber;

a second film-forming gas supply system configured to supply a second film-forming gas to the substrate within the processing chamber; and

a control unit configured to control the first and second film-forming gas supply systems to supply the first film-forming gas to the substrate within the processing chamber so as to form an intermediate film on the substrate and to supply the second film-forming gas to the substrate within the processing chamber so as to form a metal film on the intermediate film of the substrate within the processing chamber,

the metal film being more resistant to oxidation than the intermediate film, the metal film having a larger thickness than the intermediate film.

### Supplementary Note 14

According to another aspect of the present invention, there is provided a program causing a computer to perform:

forming an intermediate film on a substrate having an insulating film formed thereon by supplying the first film-forming gas to the substrate within a processing chamber; and

forming a metal film on the intermediate film of the substrate by supplying a second film-forming gas to the substrate within the processing chamber,

the metal film being more resistant to oxidation than the intermediate film, the metal film having a larger thickness than the intermediate film.

### Supplementary Note 15

According to another aspect of the present invention, there is provided a method of manufacturing a semiconductor device and a method of processing a substrate, each of which includes:

forming a metal film;

forming an insulating film; and

forming an intermediate film interposed between the metal film and the insulating film,

the intermediate film being more susceptible to oxidation than the metal film, the intermediate film having a smaller thickness than the metal film.

### Supplementary Note 16

According to another aspect of the present invention, there is provided a semiconductor device including:

a metal film formed on a substrate;

an insulating film formed above the metal film; and

an intermediate film interposed between the metal film and the insulating film, the intermediate film being more susceptible to oxidation than the metal film, the intermediate film having a smaller thickness than the metal film.

### Supplementary Note 17

According to another aspect of the present invention, there are provided a program or a non-transitory computer readable recording medium storing the program, the program causing a computer to perform:

forming an intermediate film on a substrate having an insulating film formed thereon within a first processing chamber by supplying a first film-forming gas to the substrate; and

forming a metal film on the intermediate film by supplying a second film-forming gas to the substrate within a second processing chamber,

the metal film being more resistant to oxidation than the intermediate film, the metal film having a larger thickness than the intermediate film.

Various typical embodiments described above are not intended to limit the scope of the present invention. Therefore, the scope of this invention is specified only by the claims herein.

1. A method of manufacturing a semiconductor device comprising:
forming an intermediate film on a substrate having an insulating film formed thereon; and
forming a first metal film on the intermediate film,
the intermediate film being more susceptible to oxidation than the first metal film, the intermediate film having a smaller thickness than the first metal film.

2. The method according to claim 1, wherein
the intermediate film is a second metal film made of a material different from the first metal film.

3. The method according to claim 1, wherein
the intermediate film is more susceptible to oxidation than the substrate.

4. The method according to claim 1, wherein
the intermediate film getters oxygen.

5. The method according to claim 4, wherein
the intermediate film getters oxygen diffusing from an interior of the insulating film.

6. The method according to claim 4, wherein
the intermediate film getters externally incoming oxygen that has passed through the first metal film.

7. The method according to claim 4, wherein
the intermediate film getters the oxygen, and at least a part of the intermediate film is changed into an insulating film.

8. The method according to claim 7, wherein
the intermediate film getters the oxygen, and a part of the intermediate film excluding the part changed into the insulating film is left unchanged.

9. The method according to claim 4, wherein
the intermediate film getters the oxygen, and the entire intermediate film is changed into an insulating film.

10. The method according to claim 1, wherein
a thickness of the intermediate film is set based on an amount of metal content included in the intermediate film, the amount of metal content enables gettering of at least the oxygen diffusing from an interior of the insulating film and the amount of oxygen that has passed through the first metal film.

11. The method according to claim 10, wherein
the thickness of the intermediate film ranges from 0.2 to 5 nm.

12. The method according to claim 1, wherein
the intermediate film and the first metal film are formed sequentially in one apparatus.

13. A substrate processing apparatus comprising:
a processing chamber configured to accommodate a substrate having an insulating film formed thereon;
a first film-forming gas supply system configured to supply a first film-forming gas to the substrate within the processing chamber;
a second film-forming gas supply system configured to supply a second film-forming gas to the substrate within the processing chamber; and
a control unit configured to control the first and second film-forming gas supply systems to supply the first film-forming gas to the substrate within the processing chamber so as to form an intermediate film on the substrate and to supply the second film-forming gas to the substrate within the processing chamber so as to form a metal film on the intermediate film of the substrate,
the metal film being more resistant to oxidation than the intermediate film, and the metal film having a larger thickness than the intermediate film.

14. A non-transitory computer-readable recording medium storing a program causing a computer to perform:
forming an intermediate film on a substrate having an insulating film formed thereon within a processing chamber by supplying a first film-forming gas to the substrate; and
forming a metal film on the intermediate film of the substrate by supplying a second film-forming gas to the substrate within the processing chamber,
the metal film being more resistant to oxidation than the intermediate film, and the metal film having a larger thickness than the intermediate film.
